(19) United States
(12) Patent Application Publication
(10) Pub. No.: US 2010/0282276 A1
(43) Pub. Date: Nov. 11, 2010

(54) REMOVING DEFECTS FROM PHOTOVOLTAIC CELL METALLIC SUBSTRATES WITH FIXED-ABRASIVE FILAMENT ROLLER BRUSHES

(75) Inventors: Timothy Kueper, Cupertino, CA (US); Joseph Laia, Santa Clara, CA (US); Jason Corneille, San Jose, CA (US); Philip Scott, Santa Clara, CA (US)

Correspondence Address: Weaver Austin Villeneuve & Sampson LLP, P.O. BOX 70250, OAKLAND, CA, 94612-0250, US

(73) Assignee: MIASOLE, Santa Clara, CA (US)

(21) Appl. No.: 12/842,865

(22) Filed: Jul. 23, 2010

Related U.S. Application Data
(63) Continuation-in-part of application No. 12/422,620, filed on Apr. 13, 2009.

(51) Int. Cl. B24B 1/00; B24B 55/12; B24B 7/06; B08B 7/00; H01L 31/18

(52) U.S. Cl. 134/6; 451/57; 451/53; 451/184; 438/95; 438/96; 257/E31.047; 257/E31.015

(57) ABSTRACT

Provided are methods and apparatuses for processing photovoltaic cell metallic substrates to remove various surface defects. In certain embodiments, a thin stainless steel foil is polished using a proposed method leading to a substantial, e.g., twice or more, increase in its surface gloss. In certain embodiments, a method in accordance with the present invention involves contacting a substrate surface with a fixed-abrasive filament roller brush. The brush may be a close-wound coil brush. The brush includes filaments carrying 5-20 micrometer abrasive particles that are permanently fixed in the brush filaments, for example a polymer base material, such as nylon. The particles may be made of silicon carbide and/or other abrasive materials. In certain embodiments, a substrate surface is polished using a series of roller brushes, at least two of which rotate in different directions with respect to that surface.

### CROSS-REFERENCE TO RELATED APPLICATIONS

This application is a continuation-in-part and claims the benefit of U.S. Ser. No. 12/422,620, entitled “POLISHING A THIN METALLIC SUBSTRATE FOR A SOLAR CELL,” filed on Apr. 13, 2009, which is incorporated herein by reference in its entirety for all purposes.

### BACKGROUND

Photovoltaic technology continues to develop as a renewable source of clean energy. In particular, photovoltaic cells based on a copper indium gallium diselenide (CIGS) junction offer great promise among thin-film cells, having a relatively high efficiency and low production cost. Such cells can be fabricated by chemical deposition on metallic substrates. The substrates provide support for other cell materials, e.g., absorber and contact layers, and electrical conductivity for interconnecting cells. Functional photovoltaic layers deposited on metallic substrates are often thin and sensitive to surface roughness and distortions. Currently available substrates often do not meet stringent photovoltaic fabrication requirements and have to be additionally processed before other photovoltaic materials can be deposited onto substrate surfaces. For example, stainless steel foil substrates are typically made by rolling stainless steel billets into thin flat sheets. Rolling can cause various surface defects, such as pits, protrusions, inclusions, rolling grooves and residues. These defects can in turn negatively impact the performance of a photovoltaic cell incorporating the substrate.

### SUMMARY

Provided are methods and apparatuses for processing photovoltaic cell metallic substrates to remove various surface defects. For example, a thin stainless steel foil can be polished leading to a substantial, e.g., twice or more, increase in its surface gloss. In certain embodiments, a method in accordance with the present invention involves contacting a substrate surface with a fixed-abrasive filament roller brush. The brush may be a close-wound coil brush. The brush includes filaments carrying 5-20 micrometer abrasive particles that are permanently fixed in the brush filaments, for example a polymer base material, such as nylon. The particles may be made of silicon carbide and/or other abrasive materials. A rotational axis of the brush may be substantially parallel to the substrate surface. In certain embodiments, a substrate surface is polished using a series of rollers, at least two of which rotate in different directions with respect to that surface.

In certain embodiments, a method for processing a photovoltaic cell metallic substrate to remove surface defects in accordance with the present invention involves feeding a continuous substrate web towards a fixed-abrasive filament roller brush and contacting the substrate surface with the rotating brush. This contact causes at least some defects to be removed from the substrate surface by the brush and forms a polished surface on the substrate. The brush includes a plurality of filaments with fixed abrasive particles that are between about 5 micrometers and 20 micrometers in size on average.

The abrasive particles may be made of silicon carbide. In certain embodiments, the rotational axis of the brush is substantially parallel to the substrate surface. In more specific embodiments, a brush rotates in a direction counter to the feeding direction of the substrate web. In other embodiments, the rotational axis of the brush is substantially perpendicular to the substrate surface.

In certain embodiments in accordance with the present invention, a web is fed at a speed of between about 1 foot per minute and 20 feet per minute. A brush may rotate at a rotational speed of between about 700 RPM and 1400 RPM. In certain embodiments, an average length of the brush's filaments is larger than a gap between the brush core and the substrate surface by between about 0.1 inches and 0.5 inches. In other words, there is an overlap between the brush's circumference and the substrate surface, which results in contact between the two and bending of some filaments. A brush diameter may be at least about 10 inches. A brush may be a close-wound coil brush. In certain embodiments, a loading of fixed abrasive particles in the brush's filaments is between about 20% and 35%. Brush's filaments may be between about 0.005 inches and 0.030 inches in diameter. In certain embodiments, a substrate web is at least partially supported in the contact area with the brush. For example, a substrate web may be supported by a stainless steel support roller.

In certain embodiments, a process in accordance with the present invention also involves delivering liquid into a pinch area between a brush and a substrate web. This liquid may be used for cooling and/or cleaning purposes. For example, an average temperature of the liquid may stay under a temperature limit set to prevent substantial separation of the fixed abrasive particles from the brush filaments. In specific embodiments, brush filaments include nylon that supports the fixed abrasive particles. In these embodiments, the upper temperature limit for the cooling liquid is set to less than about 50° C.

In certain embodiments, a gloss of a processed substrate surface is at least doubled during a contacting operation in accordance with the present invention. In certain embodiments, a suitable metallic substrate has a thickness of between about 0.5 mils and 15 mils, or between about 0.5 meters and 3 meters wide, and may be made of stainless steel.

In certain embodiments, a method in accordance with the present invention involves contacting a substrate surface with a first fixed-abrasive filament roller brush and then with the second fixed-abrasive filament roller brush. The second brush also rotates during the contact with the substrate surface, but it may rotate in an opposite direction relative to the first brush with reference to the polished substrate surface. In certain embodiments, the rotational axes of the first and second brushed are substantially parallel to the polished substrate surface. In more specific embodiments, the first brush rotates in a direction counter to the feeding direction of the substrate, while the second brush rotates in the same direction as the feeding direction of the substrate. In certain embodiments, the first brush rotates in a direction counter to the feeding direction of the substrate web, and the second brush rotates in the same direction as the feeding direction of the substrate web. The second brush may remove additional surface defects from the previously polished substrate surface. In certain embodiments, fixed abrasive particles of the second brush are smaller on average than that of the first brush.

In certain embodiments, a method in accordance with the present invention also involves cleaning a substrate web after one or more contacting operations described above by passing the web through one or more cleaning stations. Examples of such stations include high pressure water jets, draying air knives, rinsing jets, and rotating non-abrasive cleaning brushes. In the same or other embodiments, a web is passed through a set of two roller brushes configured to clean both sides of the substrate with a surfactant-containing water solution.

In certain embodiments, a method in accordance with the present invention also involves depositing a photovoltaic absorber layer on a polished substrate surface. Examples of absorber layers include copper indium gallium diselenide (CIGS), cadmium telluride (CdTe), and amorphous silicon (a-Si). The deposition on the metallic substrate may also include other thin film layers, for example a conductive backing layer may be disposed between the absorber layer and the metallic substrate to provide a diffusion barrier between the absorber layer and the metallic substrate.

In certain embodiments in accordance with the present invention, an apparatus for processing a photovoltaic cell metallic substrate to remove surface defects from the substrate surface is provided. The apparatus may include an unwind spool configured to feed a continuous web of the photovoltaic cell metallic substrate. The apparatus may also include a first fixed-abrasive filament roller brush including multiple filaments containing fixed abrasive particles. These particles may be between about 5 micrometers and 20 micrometers in size on average. A rotational axis of the brush may be substantially parallel to the substrate surface. The apparatus may also include a rewind spool configured to take up the web with a polished substrate surface.

These and other aspects of the invention are described further below with reference to the figures.

### BRIEF DESCRIPTION OF THE DRAWINGS

FIG. 1 is a schematic representation of a cross-sectional profile of a photovoltaic cell in accordance with certain embodiments.

FIGS. 2A and 2B illustrate various examples of substrate surface defects and resulting shunt defects on a fabricated photovoltaic cell in accordance with certain embodiments.

FIG. 3 is a process flowchart representing a technique for processing a photovoltaic cell metallic substrate to remove surface defects from the substrate surface in accordance with certain embodiments.

FIGS. 4A and 4B are schematic representations of a filament roller brush before and after contacting a substrate surface in accordance with certain embodiments.

FIG. 5A is a schematic representation of a filament of a fixed-abrasive filament roller brush in accordance with certain embodiments.

FIG. 5B is a magnified cross-sectional image of a filament of a fixed-abrasive filament roller brush.

FIG. 6 illustrates two examples of close-wound coil type roller brushes.

FIG. 7 is a schematic representation of an apparatus for processing a photovoltaic cell metallic substrate to remove surface defects from the substrate surface in accordance with certain embodiments.

FIG. 8 is a process flowchart representing a technique for fabricating a photovoltaic cell including an operating for removal surface defects from a surface of the metallic substrate in accordance with certain embodiments.

### DETAILED DESCRIPTION OF EXAMPLE EMBODIMENTS

In the following description, numerous specific details are set forth in order to provide a thorough understanding of the present invention. The present invention may be practiced without some or all of these specific details. In other instances, well known process operations have not been described in detail to not unnecessarily obscure the present invention. While the invention will be described in conjunction with the specific embodiments, it will be understood that it is not intended to limit the invention to the embodiments.

### Introduction

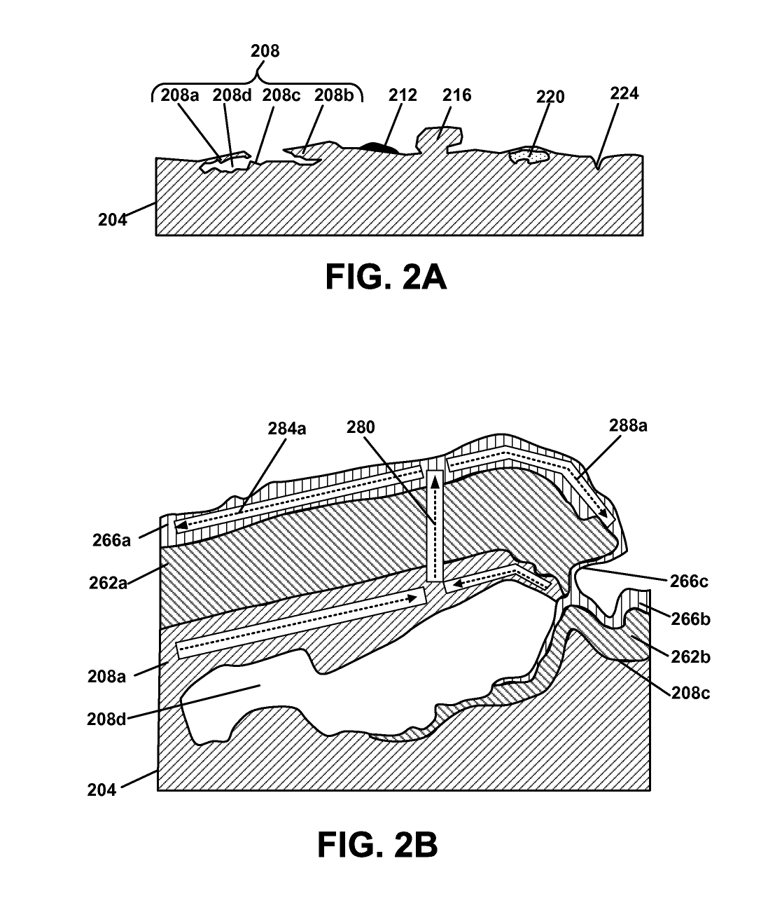

Photovoltaic cell fabrication often involves depositing one or more functional photovoltaic layers, such as conductive back and front layers and an absorber layer, on a metallic substrate. These functional layers may be very thin (e.g., 100-500 nanometers) and may require a highly polished substrate surface for deposition. Surface distortions can lead to severe defects in photovoltaic cells. For example, a high extension (e.g., bump) or a deep cavity (e.g., a pit) on a substrate surface can result in a discontinuous absorber layer that can cause shunt formation as further explained in the context of FIG. 2B. As such, photovoltaic metallic substrates have specific requirements with respect to their surface conditions and often need to be additionally processed before being used in photovoltaic cell fabrication.

Provided are methods and apparatuses for removing various surface defects from metallic substrates. In a specific embodiment, a 5-20 mil think stainless steel foil is contacted by a fixed-abrasive filament roller brush. The filaments of the brush include silicon carbide abrasive particles that are 5-20 micrometers in size on average. The brush rotates at a speed of about 700-1400 RPM while contacting the substrate surface. Water may be delivered into a pinch point between the brush and substrate for temperature control and/or contaminant removal. The polished substrate is then cleaned, rinsed, and dried. This polishing process substantially increases the gloss of the substrate surface, e.g., at least twice in certain embodiments. These methods and apparatuses may be a part of larger photovoltaic cell fabrication processes, e.g., represent one or more upstream operations.

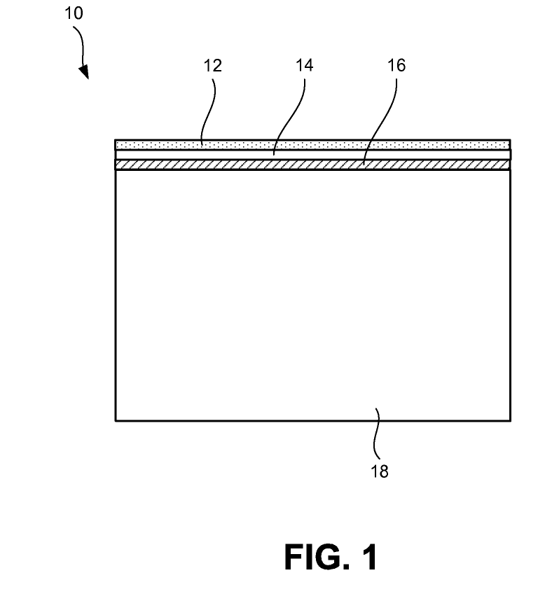

To provide a better understanding of the methods and apparatuses of the present invention, a structure of a typical thin film photovoltaic cell 10 will now be briefly described with reference to FIG. 1. The cell 10 includes a stack of multiple layers: metallic substrate 18, conductive back layer 16, semiconductor junction 14, and conductive front layer 12. The metallic substrate 18 may be used as a mechanical support for other layers and, in certain embodiments, as an electronic pathway for a photovoltaic current. Examples of substrate materials include stainless steel (e.g., 430-alloy stainless steel), titanium, copper, aluminum, beryllium, aluminum-silicon alloys, titanium-aluminum alloys, and metalized non-metallic materials, (e.g., a polymer substrate with a sputtered metallic layer). Such materials are collective referred to as metallic substrates because they contain at least some metal. In certain embodiments, a metallic substrate is between about 0.5 mils and 50 mils thick or, more particularly, between about 2 mils and 20 mils thick, or about 10 mils thick. Other thickness values are also within the scope of the invention. It should be noted a typical metallic substrate is substantially thicker than other layers in the stack as schematically represented in FIG. 1. Therefore, even small surface defects on the substrate may be highly detrimental to other functional layers.

In certain embodiments, a substrate received from a substrate supplier (e.g., a steel mill) have a surface roughness of at least about 1 micrometer before additional processing or, more particularly, at least about 5 micrometers and even at least about 10 micrometers. In the same or other embodiments, a received substrate has a gloss of less than 200 (measured at a 20° angle using a typical gloss measuring technique) or, more particularly, less than about 150 or less than about 100 or even less than about 50. It has been determined that such substrates are not suitable for deposition of high quality functional layers onto their surfaces. Surface roughness and other defects will lead to many defects in resulting photovoltaic cells, such as shunts. While such cells may still be usable, in general, their performance characteristics are substantially worse than characteristics of cells fabricated using a polished substrate. As such, substrate surfaces need to be polished and/or cleaned to meet stringent requirements of photovoltaic fabrication in order to yield high efficiency photovoltaic cells.

A semiconductor junction 14, which is also referred to as an absorber layer, is configured to generate a voltage when its front surface, i.e., the surface facing the conductive front layer 12, is exposed to sunlight. This voltage in turn drives a photovoltaic current in the cell. In certain embodiments, the semiconductor junction 14 includes cadmium-telluride (Cd—Te), copper-indium-gallium-selenide (CIGS), or amorphous silicon (a-Si), for example. A typical thickness of a CIGS junction, for example, is between about 100 nanometers and 3,000 nanometers or, more particularly, between about 200 nanometers and 800 nanometers.

A conductive back layer 16 may be positioned between the semiconductor junction 14 and metallic substrate 18 to provide diffusion barrier, light reflecting, and other properties. This layer 16 may be made from molybdenum, niobium, copper, and/or silver. The cell 10 is also shown with a conductive front layer 12. This layer typically includes one or more transparent conductive oxides (TCO), such as zinc oxide, aluminum-doped zinc oxide (AZO), indium tin oxide (ITO), and gallium doped zinc oxide. A typical thickness of a TCO layer is between about 100 nanometers and 1,000 nanometers or, more particularly, between about 200 nanometers and 800 nanometers. As such, a 5 micrometer (5,000 nanometers) substrate surface scratch is much larger than any other layers in the stack making it difficult or impossible to form uniform photovoltaic functional layers on such rough substrate surfaces. This is further illustrated with reference to FIGS. 2A and 2B.

FIG. 2A illustrates examples of various substrate surface defects in accordance with certain embodiments. These and other types of defects can be at least partially removed using the novel methods and apparatuses described herein. Specifically, FIG. 2A illustrates examples of pit 208, residue 212, protrusion 216, inclusion 220, and rolling groove 224. The pit 208 may include left over-hanging portion 208a and right over-hanging portion 208b, which may result, for example, from metallic flakes and/or protrusions rolled onto the substrate surface. The pit 208 may also include recessed portion 208c and cavity portion 208d. The residue 212 may include oil used during substrate rolling, carbon contain materials used for steel manufacturing, and other contaminants. The protrusion 216 may be caused by small pieces extending from the billet during rolling. The inclusion 220 may be generated by surface oxides and other contaminants rolled into the substrate body, i.e., under but near its surface. Such inclusions can form later surface defects, for example, during deposition of functional layers and/or negatively impact various surface characteristics of the substrate, e.g., roughness, resistivity. The rolling groove 224 may be caused by direct interaction of the billet surface with the roller when the billet is thinned down to the rolled sheet stock. Rolls used for substrate fabrication often have surface defects themselves that cause substrate surface defects.

FIG. 2B illustrates an expanded view of a pit portion, similar to the one shown in FIG. 2A, after forming two functional layers on the substrate surface. The cavity 208d of the pit causes the semiconductor junction layer to form two locally disconnected portions, i.e., left junction portion 262a and right junction portion 262b. FIG. 2B also illustrates three portions of a TCO layer, i.e., a left TCO portion 266a disposed over the left junction portion 262a, a right TCO portion 266b disposed over the right junction portion 262b, and a center TCO portion 266c disposed on the side-wall of the discontinuous junction layer. A conductive back layer (e.g., a molybdenum layer), current collectors (e.g., a wire network), and other photovoltaic cell parts are not shown in FIG. 2B for simplicity. However, one having ordinary skills in the art would appreciate that presence of other cell elements may result in additional problems caused by substrate surface defects. For example, current collectors can concentrate photovoltaic currents that further increase the risk of shunt formation.

Uneven distribution of the functional layers, more particularly a discontinuous semiconductor junction layer, can cause undesirable shunts as well as other cell defects. A shunt shown in FIG. 2B is caused by a photocurrent 280 generated in the left junction portion 262a that passes from the left over-hanging portion 208a to the left TCO portion 266a. This photocurrent 280 divides into two separate portions based on respective electrical resistances of the components: a load portion 284a, which passes to the left through the left TCO portion 266a, and the shunt portion 288a, which passes to the right through the TCO portions 266a and 266c. The shunt electrical current portion 288a leads to loss of solar cell efficiency, may generate hot spots that can melt and permanently damage the entire cell, as well as other problems. Therefore, it is desirable to eliminate or at least minimize such defects in photovoltaic cells, particularly those caused by surface defects of metallic substrates. It has been determined that removing surface defects using the methods and apparatuses described herein can substantially reduce defects in photovoltaic cells. Metal substrates processed in accordance with these methods and using these apparatuses have demonstrated substantial improvement in gloss and other surface properties. While some small scratches may remain on the polished substrate surfaces, these scratches are relatively small and generally do not cause cell defects.

### Defect Removal Process Examples

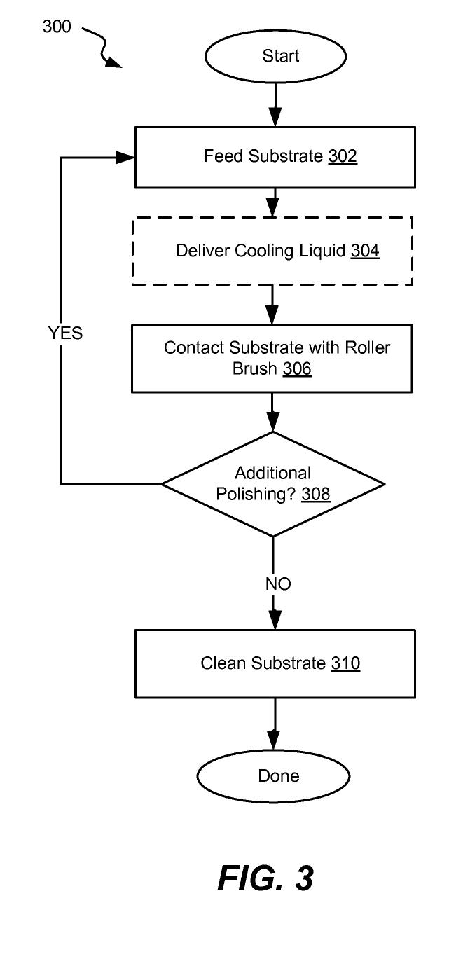

FIG. 3 is a flowchart corresponding to a technique for removing surface defects from a metallic substrate surface in accordance with certain embodiments of the present invention. The process 300 begins with feeding a continuous web of a metallic substrate towards a roller brush (block 302). Various substrate examples are described above. In certain embodiments, a web has a width of between about 0.3 meters and 3 meters or, more particularly, between about 0.5 meters and 2 meters. Various web tensioning and handling mechanisms may be implemented. A web may be fed at a speed of between about 1 foot per minute and 20 feet per minute or, more particularly, between about 5 feet per minute and 15 feet per minute. A feeding speed, in addition to other process parameters, in part determines extent of contact between the substrate surface and the brush and, as a result, extent of polishing. Other factors include the size and other characteristics of the brush, the number of brushes used to polish one surface, and the rotating speed of the brush. The feeding speed may be controlled by a rewind (i.e., take-up) spool, while tension control may be achieved, at least in part, by an unwind spool.

In certain embodiments, one or more surface properties (e.g., gloss) are measured before and/or after polishing the substrate. This information may used to control various process parameters, such as feeding speed, rotational speed of the roller brush, overlap between the substrate surface and the roller brush, cleaning station processing parameters, and others. In certain embodiments, the process 300 involves measuring gloss of the fed web and then measuring gloss of the polished web, either before or after cleaning operations.

In certain embodiments, the process 300 involves delivering a liquid into a pinch area between the rotating brush and substrate (block 304), i.e., wet polishing is performed at 306. This operation is optional, and in other embodiments, the process 300 can be performed without wetting a brush, i.e., dry polishing is performed at 306. A liquid delivered at 304 may be water (e.g., deionized water). It can be used to control a brush temperature and/or to remove particles and other contaminants from the substrate surface. Keeping the brush temperature below a certain predetermined level can preserve its integrity and abrasive characteristics. Fixed-abrasive filament roller brushes typically have polymer materials supporting abrasive particles. When such brushes heat up, the polymer materials soften and tend to loose abrasive particles faster leading to brush degradation. For example to cool a nylon brush, a liquid temperature may be kept at less than about 50° C. Other upper temperature limits may be used for other polymer materials depending of their heat resistant characteristics.

A delivered liquid may include one or more surfactants to help remove loose particles and contaminants generated during polishing. In certain embodiments, a polishing compound can be applied to a roller brush or a substrate surface. For example, 3M Perfect-It™ Paste Rubbing Compound, Part No. 06198 and/or 3M Perfect-It™ 3000 Extra Cut Rubbing Compound, Part No. 6060, available from 3M, St. Paul, Minn., can be used. In general, polishing compounds can be used together with fixed-abrasive filament roller brushes or in separate stations with non-abrasive roller brushes.

The process 300 proceeds with contacting a substrate surface with a rotating brush (block 306). In certain embodiments, a brush rotates at a speed of between about 300 RPM and 3000 RPM or, more particularly, between about 700 RPM and 1400 RPM. The brush's rotational axis may be substantially parallel to the substrate surface. In certain embodiments, a brush rotates in a direction that is opposite to the feeding direction of the substrate at the contact point. In other embodiments, a brush rotates in the feeding direction. In embodiments where multiple brushes are used to polish the same substrate surface, at least two of these brushes may rotate in opposite directions with respect to the polished surface. It has been determined that such configuration provides more efficient polishing. Without being restricted to any particular theory, it is believed that by rotating two brushes in opposite directions, residual defects left and/or generated by the first brush are more effectively removed by the second brush because of the residual defects' orientations relative to the rotation direction of the second brush. For example, if an extending burr was not removed by the first brush but only bent in the direction of the first brush rotation, then the second brush rotating in the opposite direction is more likely to remove this bent burr. In certain embodiments, the first brush rotates in a direction counter to the feeding direction of the substrate web, and the second brush rotates in the same direction as the feeding direction of the substrate web. In other embodiments, the rotational axis of a brush is substantially perpendicular to a polished surface. When multiple brushes are used to polish the same surface portions, at least two brushes may rotate in opposite directions (clockwise and counterclockwise with respect to the polished substrate surface) for reasons explained above.

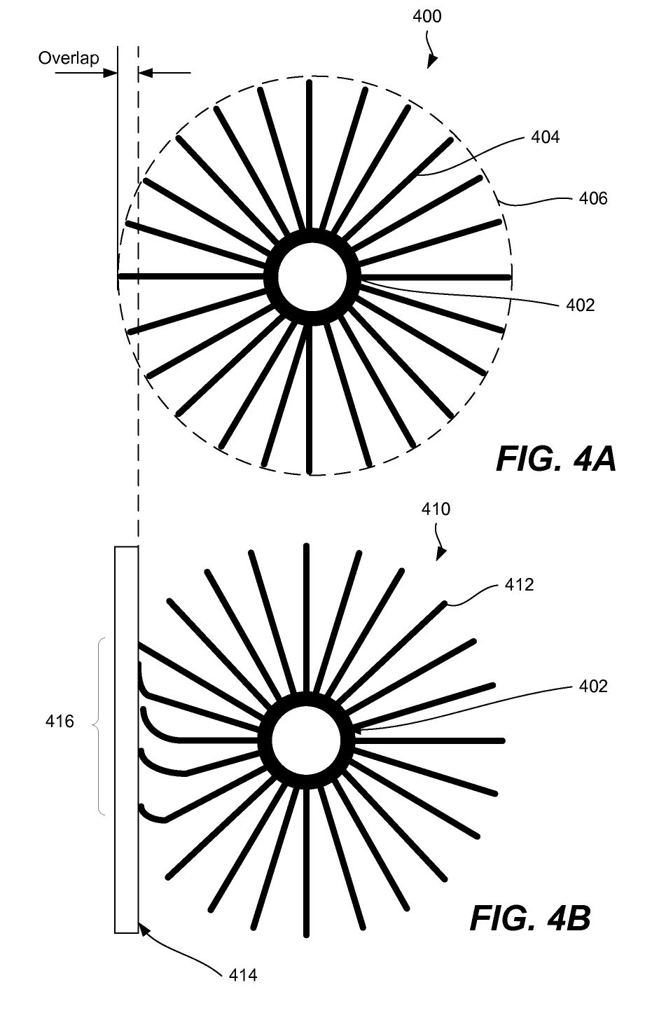

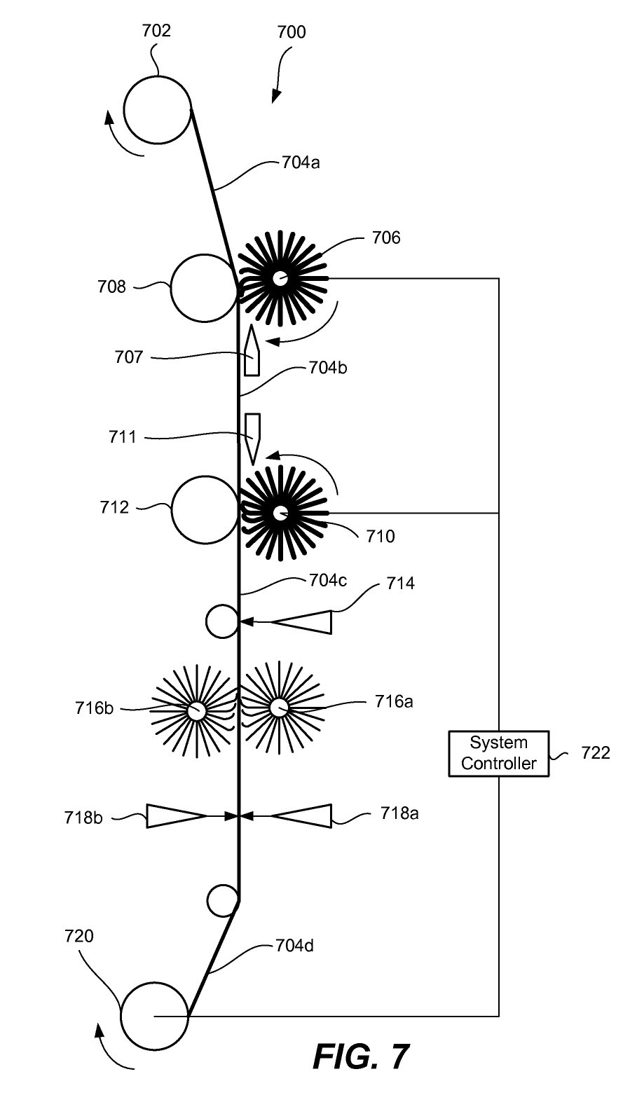

A brush may be at least about 10 inches in diameter or, more particularly, at least about 16 inches in diameter. In specific embodiments, a brush is about 20 inches in diameter. When a brush contacts a substrate surface, its outer periphery at least partially overlaps with the substrate surface in order to establish contact between the filaments and surface. This overlap causes some of the filaments to bend as illustrated in FIGS. 4A and 4B. Specifically, FIG. 4A illustrates a free-standing roller brush 400 before it contacts a substrate. The brush 400 includes a brush core 402 and multiple filaments 404 extending from the core 402. Free ends of these filaments 404 define the outer periphery 406 of the brush 400. FIG. 4B illustrates a brush 410 that is in contact with the substrate surface 414. A backing roller (e.g., elements 708 and 712 in FIG. 7) or backing plate may be used to control the position of the substrate with respect to the brush or, more particularly, to control the position of the polished foil surface with respect to the free ends of the filaments. In other embodiments, line tension is used for the same purpose. At least some filaments are bent because the gap between the brush core 402 and the substrate surface 414 is less than filaments' lengths. In certain embodiments, the difference between the gap and filaments' lengths is between about 0.1 inches and 0.5 inches or, more particularly, between 0.2 inches and 0.4 inches. This difference can be also referred to as an overlap between the outer periphery 406 and the substrate surface 414, or simply as an overlap between the brush and substrate.

A fixed-abrasive filament roller brush that has filaments with fixed abrasive particles is used in at least one operation 306. Abrasive particles in this brush may be supported by a polymer material forming the body of each filament. Abrasive particles may be made of diamond, aluminum oxide, silicon carbide, boron carbide, cubic boron nitride, cerium oxide, silicate, tin oxide, tungsten carbide, zirconia, fused or sintered crystalline inorganic materials, as well as other materials. Particles may be between about 1 micrometers and 100 micrometers in size or, more particularly, between about 5 micrometers and 20 micrometers. In specific embodiments, silicon carbide particles that are between about 5 micrometers and 20 micrometers in size are used for polishing stainless steel foil. It has been found that for a typical rolled stainless steel substrate smaller particles (e.g., <1 micrometer) do not provide adequate polishing, while larger particles (e.g., >25 micrometers) generate scratches that are too large and may be damaging to subsequently formed functional photovoltaic layers. In addition to size and materials, abrasive particles may be characterized based on their shapes (e.g., flakes, beads, cones, irregular, cylindrical, pyramids) and circularity (e.g., between about 0.75 and 1, between about 0.8 and 0.95).

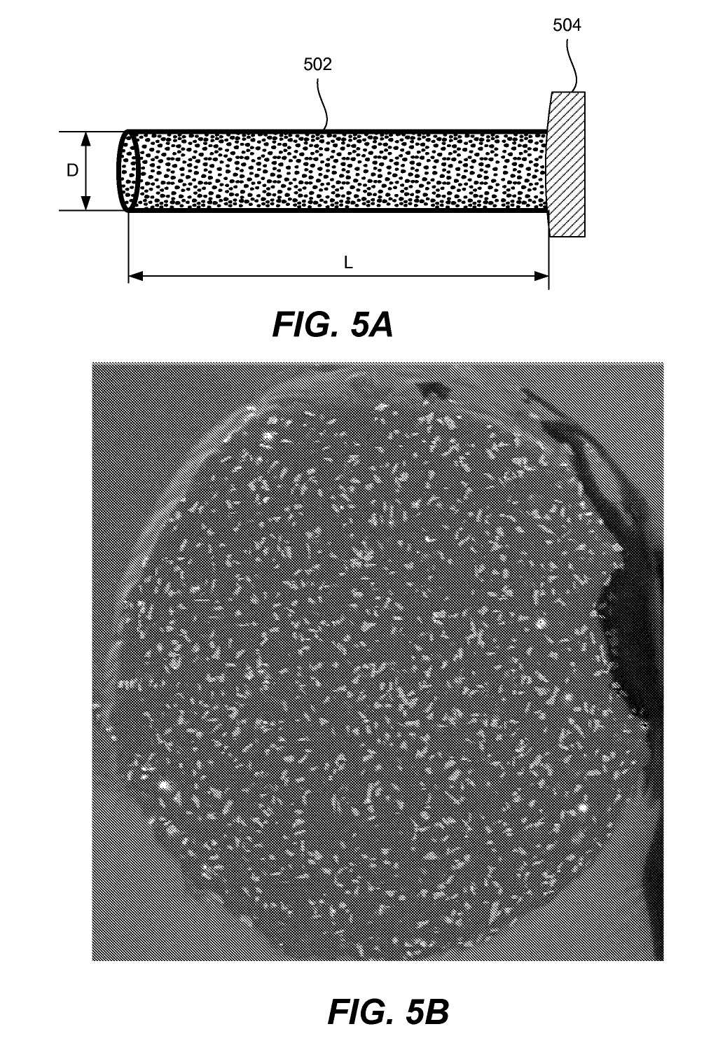

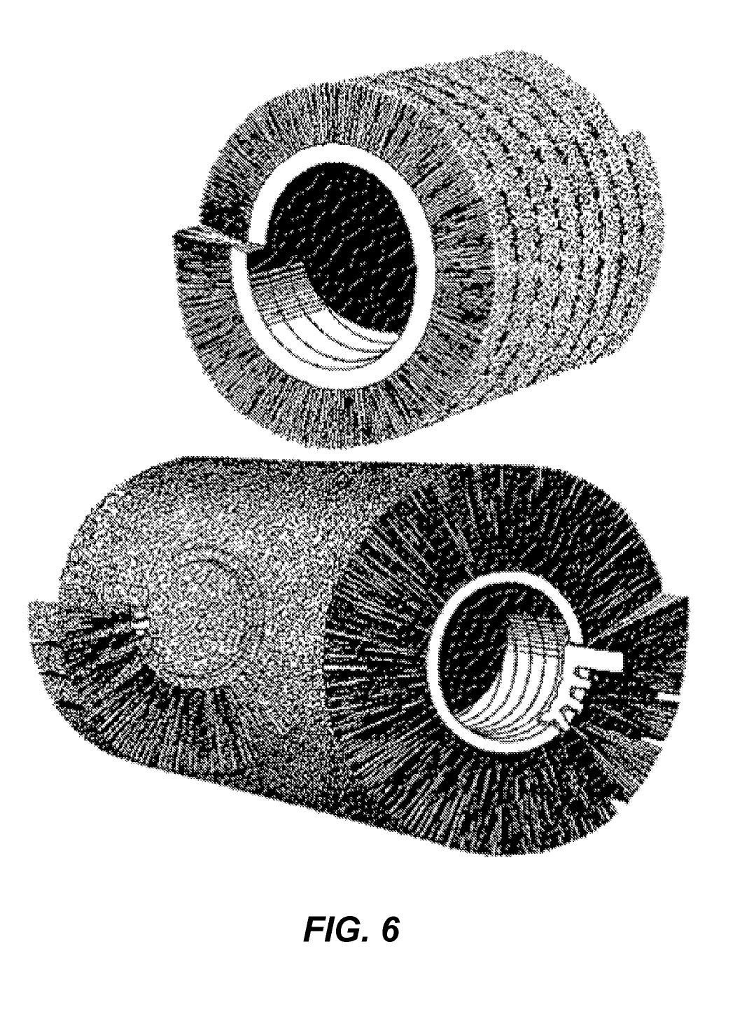

FIG. 5A is a schematic representation of a filament 502 attached to a brush core 504 in accordance with certain embodiments. Suitable filaments may have a diameter of between about 0.005 inches and 0.030 inches or, more particularly, between about 0.012 inches and 0.024 inches, or about 0.018 inches. In other embodiments, filaments with a smaller diameter may be used, for example, between about 0.003 inches and 0.020 inches or, more particularly between about 0.005 inches and 0.012 inches, or between about 0.008 inches and 0.010 inches. Filaments may have a length of between about 2 inches and 6 inches or, more particularly, about 4 inches. In a specific example, a 20-inch roller brush with a 12-inch core has filaments that are approximately 4 inches long. FIG. 5B illustrates a magnified cross-sectional image of a filament in accordance with one embodiment of the invention further exemplifying relative sizes and distribution of abrasive particles within the filament. In certain embodiments, fixed abrasive particles have a loading of between about 20% and 40% or, more particularly, around 30%. A fixed-abrasive filament roller brush may be a close-wound coil brush based on the arrangement of filaments. Examples of such brushes are illustrated in FIG. 6. By varying a pitch between each coil in close-wound coil brushes, a wide range of brush densities can be achieved. Radial bristles brushes may also be used. In addition to filament brushes, fixed abrasive brushes may be made from Scotch Brite™ type buns or bristle shaped composite brushes.

Returning to FIG. 3, during operation 306 at least some defects are removed from a substrate surface by a rotating brush. In certain embodiments, additional polishing of the same surface or another surface is needed (block 308). In these embodiments, a web may be fed towards another roller brush or redirected/rewound and fed towards the same brush. For example, one brush may be used to contact a web at two different locations along the length of the web. If multiple brushes are used, another brush may also be a fixed-abrasive filament brush or another type brush. For example, a non-abrasive brush may be used with a polishing compound applied to this brush in a subsequent polishing operation. A first brush and a second brush may rotate in opposite directions with respect to the polished substrate surface as explained above. In certain embodiments, a second brush is a fixed-abrasive filament brush with different abrasive particles. For example, a second brush may have finer grit (i.e., smaller particles) than the first brush. In certain embodiments, the same surface is polished by a series (e.g., 3, 4, 5, 6, etc.) of roller brushes with progressively finer grits. Rotational directions of these brushes may alternate. In various embodiments, one or both sides of the substrate are polished.

The process 300 may proceed with substrate cleaning (block 310). For example, a substrate may be passed through one or more cleaning stations that include water jets, cleaning brushes, rinsing devices, and/or air drying knives. In certain embodiments, a substrate is fed through a set of cleaning jets configured to deliver a cleaning liquid (e.g., deionized water) to a polished substrate surface. In specific embodiments, a cleaning liquid may be delivered at a pressure of at least about 100 psi, at least about 200 psi, or at least about 500 psi. Washing operations may be performed while the washed substrate surface is positioned downward to add a gravitation component to water draining and contaminant removal.

In the same or other embodiments, a substrate is fed through one or more cleaning brushes. Such brushes may also have polymer filaments (e.g., similar to ones described above) but may not contain abrasive particles inside the filaments. A cleaning brush may be between about 2 inches and 10 inches in diameter or, more particularly, about 6 inches in diameter. In certain embodiments, a cleaning brush rotates at between about 50 RPM and 300 RPM or, more particularly, around 100 RPM. In the same or other embodiments, a substrate is passed through a cleaning station that includes two roller brushes configured to contact both sides of the substrate at approximately the same location. Cleaning brushes typically used in a combination with one or more cleaning liquids. For example, a water solution containing a surfactant may be used.

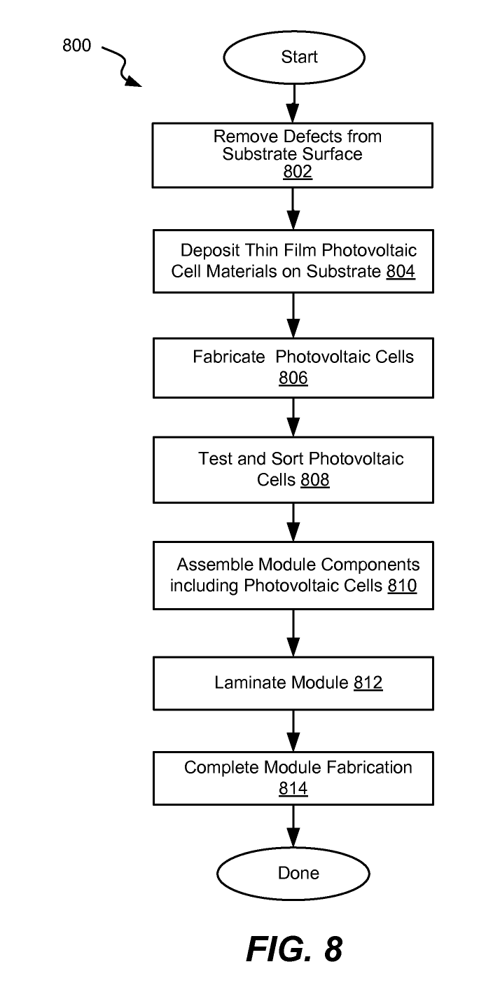

Cleaning may also involve rinsing a substrate with water sprayed on one or both sides of the substrate. In certain embodiments, a series of spray manifolds each with a flow of up to 3 gallons or more of water per minute may be delivered onto a 1 meter wide substrate that is fed at a speed of about 15 feet per minute. Cleaning typically involves a drying step. For example, a substrate may be fed through a series of drying air knives. The substrate may be then wound on a take up spool. In certain embodiments, a gloss of the substrate surface at the end of the process is at least double that at the beginning of the process. At this point, a polished surface is configured to receive at least one photovoltaic functional layer as further described with reference to FIG. 8.

### Apparatus Examples

FIG. 7 is a schematic representation of an apparatus 700 for removing surface defects from metallic substrate surfaces in accordance with certain embodiments of the present invention. A substrate web 704a containing defects may be supplied from an unwinding roller or spool 702. The web passes through a series of processing stations that are configured to polish, clean, and/or dry the substrate before it is taken up on a take-up roller or spool 720. The unwinding roller 702 and the take-up roller 720 are configured to control the web tension and speed as the web passes through these processing stations.

After unwinding, the substrate 704a may be fed towards a first polishing roller brush 706. Various brush examples are described above. At least one polishing roller of the apparatus 700 is a fixed-abrasive filament roller brush. The substrate 704a then contacts the first roller brush 706. At the contact area, the substrate 704a may be supported by a first supporting roller 708. A supporting roller may be made of stainless steel or other suitable materials. A supporting roller may have a smaller diameter than a roller brush yet still provide adequate support to the substrate in the contact area. In certain embodiments, both the supporting roller 708 and the polishing brush 706 extend beyond the foil width. This configuration can be used to remove defects from one or both edges of the substrate in addition to the polished surface.

A series of spray nozzles 707 may be used to deliver liquid streams into a pinch point between the brush 706 and the substrate 704a during wet polishing described above. A position of spray nozzles with respect to a roller brush (i.e., before or after the roller brush relative to the web feeding direction) is typically determined based on a rotating direction of the brush. A linear speed of the brush in the contact area is generally much faster than the web feeding speed. As such, a liquid needs to be delivered (and spray nozzles positioned) such that the rotation of the brush pulls the liquid into the contact area instead of pushing it away from the area. In other words, if a roller brush scratches a substrate surface in the direction opposite of the web feeding, as for example the roller brush 706 in FIG. 7, then spray nozzles should be positioned after the brush. However, if a roller brushes scratches a substrate surface in the direction of the web feeding (e.g., roller brush 710 in FIG. 7), then the spray nozzles should be positioned before the brush. It should be also noted that spray nozzles may also deliver liquid at other parts of roller brushes and/or substrate web. Furthermore, in certain embodiments, dry polishing may be performed and spray nozzles may not be a part of the apparatus or may be temporarily or permanently out of use. In certain embodiments, some polishing stations (e.g., a combination of a roller brush, a supporting roller, and spray nozzles if they are used) are configured for dry polishing, while others are configured for wet polishing.

An apparatus may be equipped with various metrology devices, for checking process parameters and/or materials characteristics. For example, an apparatus may have one or more temperature sensors to control a temperature of the liquid collected from a polishing station or a temperature of the substrate leaving the polishing area. This temperature information may be used to control a flow rate of the liquid through the spray nozzles. In certain embodiments, an apparatus includes one or more gloss measuring devices. Such devices may used to check the gloss of a provided substrate (e.g., substrate 704a in FIG. 7), gloss of a substrate after each polishing station (e.g., substrates 704b and 704c), and a fully processed substrate (e.g., substrate 704d). Gloss information may be used to control various process parameters, such as rotational speeds and/or overlaps of roller brushes, and identifying worn of roller brushes. In certain embodiments, metrology devices are connected to the system controller 722 further described below.

A substrate 704b partially polished by the first roller brush 706 may be fed towards a second polishing roller brush 710 for additional polishing. As described above, the second brush 710 may have the same or different abrasive material, for example, a finer grit. In certain embodiments, an apparatus may include additional brushes for polishing the same or the other surface. For example, an apparatus may include a series of brushes with progressively finer grit to achieve adequate polishing results. In some embodiments, one roller brush may be used for two or more polishing operations of the same substrate. For example, a substrate web may first come in contact with one part of the brush circumference. The web may then be turned with a set of web handling rollers and fed back towards the brush to contact another portion of the circumference (e.g., about 180° opposite of the first contact point). In other words, the same brush may effectively perform as two or more brushes.

The second brush 710 may rotate in the same direction or different direction (shown) than the first brush 706 with respect to the substrate surface. The substrate 704b may also be supported in the contact area by a second supporting roller 712. A set of spray nozzles 711 are shown to be positioned before the brush 710. As explained above, a rotating direction of the brush determines the position of the nozzle. Since the second brush 710 rotates in a direction of the substrate web feeding, the spray nozzles 711 are positioned before the brush.

The polished web 704c may be then fed into a series of cleaning stations to removed loose particles and other contaminants generated during polishing. FIG. 7 illustrates the apparatus 700 with three cleaning stations: a high pressure washing station 714, a set of non-abrasive cleaning rollers 716a and 716b, and a set of drying air knives 718a and 718b. Examples of other suitable cleaning stations include vacuum cleaning stations, electrostatic cleaning stations, and wiping stations.

In the high pressure washing station 714, a substrate web may be supported when high pressure jets hit its surface to prevent substrate ripping and other damage. A supporting roller similar to the ones described above can be used for these purposes. Pressure settings for a pressure washing station are described above. The jets may be positioned at an oblique angle with respect to the substrate surface to help separating residues from the substrate surface. In the same or other embodiments, a substrate web makes a sharp turn over a small diameter support roller of the pressure washing station while being sprayed with the liquid.

Two cleaning rollers 716a and 716b may form one or two separate cleaning stations. In the embodiment shown in FIG. 7, the cleaning rollers 716a and 716b are positioned on the opposite sides of the substrate and make contact with the substrate in the same location. In this configuration, the cleaning rollers 716a and 716b rotate in the same direction with respect to the substrate, e.g., in the direction of the substrate feeding as shown in FIG. 7. In certain embodiments, a cleaning liquid is provided into such a cleaning roller station. As mentioned above, a cleaning liquid may have one or more surfactants.

In certain embodiments, a substrate is fed through a rinsing station (not shown). For example, a previous cleaning operation may leave some residues that need to be removed prior to drying, e.g., particles, surfactants. A rinsing station may be used to deliver large volumes of liquid to remove such residues, for example with a series of spray manifolds. In certain embodiments, a foil may be fed through a rinsing liquid pool. For example, one roller may be positioned at a bottom of the pool leading a web first into the pool and then out of the pool.

Often a last station in a sequence of cleaning station is a drying station. As mentioned above various liquids may be used in the pressure washing, roller cleaning, rinsing, and other stations. Residues of such liquids need to be removed from a substrate before it is wound into a roll. It is often more desirable to mechanically remove liquid residues than to evaporate them, which may lead to the stain spots. In certain embodiments, a set of air knives 718a and 718b are used for this purpose. The air knives may be positioned at an oblique angle with respect to the feeding direction of the substrate web to gradually move liquid residues towards web edges as the web is fed through the station. Finally, the cleaned substrate may be then fed into onto a rewind roller 720. It should be noted that the same substrate may be fed through the same apparatus multiple times to further improve its surface properties.

The apparatus may also include a system controller 722 for controlling various stations and devices of the apparatus, such as a unwind roller (e.g., its tension), polishing brushes (e.g., their rotational speeds, overlaps, liquid supply), cleaning stations, a rewind roller (e.g., a web feeding speed), and/or metrology devices. In certain embodiments, a system controller 722 is employed to control process conditions during feeding a substrate towards a roller brush, contacting a substrate surface with one or more brushes, cleaning the substrate and other process operations. The controller will typically include one or more memory devices and one or more processors. The processor may include a CPU or computer, analog and/or digital input/output connections, stepper motor controller boards, etc.

In certain embodiments, a system controller 722 controls some or all functions of the apparatus 700. So as not to obscure features of the invention, the system controller is shown in FIG. 7 as being directly connected to only some components of the system. It should be understood that the controller may and often will be connected with other or all components of the system. The controller 722 may be configured to execute system control software including sets of instructions for controlling a substrate feeding speed, a rotating speed of each roller brush, an overlap of each roller brush with the substrate surface, and/or various functions of cleaning stations. Other computer programs stored on memory devices associated with the controller may be employed in some embodiments. The computer program code for controlling the processing operations can be written in any conventional programming language, such assembly language, C, C++, Pascal, Fortran, Relay Ladder Logic, and others. Compiled object codes and/or scripts are stored in a tangible computer readable medium and are executed by the processor to perform the tasks identified in the program.

Typically there will be a user interface associated with the system controller 722. The user interface may include a display screen, graphical software displays of the apparatus and/or process conditions, and user input devices, such as pointing devices, keyboards, touch screens, etc. Other inputs may be provided from various sensors, such as a gloss measuring device.

In certain embodiments, an apparatus may include laser ablation stations and/or electrochemical etching stations. Similar to the polishing stations described above, these stations may be used to remove defects from surfaces of metallic substrates used in photovoltaic cell fabrication. However, these techniques are generally slower and more expensive that mechanical polishing with a fixed-abrasive filament roller brush and, therefore, may be limited for specific applications.

### Photovoltaic Cell Fabrication Process Examples

Various techniques for removing surface defects from metallic substrate surfaces may be a part of larger photovoltaic cell fabrication processes. FIG. 8 is a process flowchart representing one example of such a larger process. At 802, a substrate provided into the process 800 is processed (e.g., polished, cleaned, and/or dried) to remove various surface defects from the substrate surface. Examples of substrates and defect removal techniques are described above. After operation 802, the substrate may have acceptable surface characteristics (e.g., surface roughness, cleanness) for depositing photovoltaic thin film layers. At 804, one or more functional photovoltaic layers are deposited on the polished substrate surface forming a photovoltaic stack. A stack includes at least a light absorbing layer deposited at operation 804 on a substrate polished at operation 802. A stack may also include conductive back and front layers and/or other components. Some examples of deposition techniques include Physical Vapor Deposition (PVD), Atomic Layer Deposition (ALD), and Chemical Vapor Deposition (CVD).

At 806 photovoltaic cells are fabricated from stacks formed at 804. According to various embodiments, fabricating may involve arranging and connecting any or all of wiring, laminating and cutting stacks to produce individual cells, e.g., of dimensions of around 12.3″×1.3″. In general, photovoltaic cells of any dimension may be fabricated in this operation. At 808 photovoltaic cells are then tested and sorted to remove any cells that have poor photovoltaic efficiency or output, e.g., below a certain threshold.

At 810 photovoltaic module components are assembled and may include photovoltaic cells, electrical bus wiring, and diodes. In certain embodiments, wiring or otherwise interconnecting the cells may take place at this operation rather than at operation 806. In certain embodiments, one or more encapsulating layers may also be added to the assembly. The module assembly including photovoltaic cells is then laminated at 812. At 814 various post-lamination processes, including attaching junction boxes, module testing, etc. may then be performed to complete fabrication.

According to various embodiments, the presence and order of various operations in the process 800 may vary. For example, in the case of a process incorporating monolithically interconnected cells, the substrate is typically not cut to define individual cells at 804, though it may be cut to define a module. A separate wiring operation is also not performed, as cell interconnections are formed during thin film deposition. Positioning of individual cells is also not necessary, though other module assembly operations may still be performed. In other embodiments, various operations may be performed in other sequences.

### Experimental Examples

Various experiments were conducted to determine specific apparatus configurations and process parameters that can be used to achieve substrate surface conditions adequate for photovoltaic fabrication. Gloss measurements were typically used in these experiments for relative comparison of the process parameters. All gloss values were measured at 20° using a standard gloss measuring technique.

In one experiment, dry polishing was compared to wet polishing. During wet polishing, deionized water was delivered into a pinch point between the rotating roller brushes and substrates as described above. Two types of brushes were used to provide additional references. One brush was a flap bush with 12 micrometer silicon carbide particles, while another brush was a filament brush in accordance with the present invention with 20 micrometer silicon carbide particles. Both brushes demonstrated substantially better performance (i.e., higher resulting gloss of the polished surfaces) when wet polishing was used. The results of this experiment are summarized in the table below. While there were no obvious differences between scratch sizes, which is primarily determined by the abrasive media size, it was observed that dry polishing leaves much residue after polishing that often cannot be later removed during cleaning operations. Furthermore, it was observed that wet polishing produces more uniform surface finish.

| GLOSS VALUES | Dry Polishing | Wet Polishing |
|---|---|---|
| Flap Brush | 217 | 412 |
| Filament Brush | 341 | 570 |

In another experiment, a flap brush was compared to a filament brush in accordance with the present invention. The two types of brushes were selected with approximately the same sizes of abrasive particles, i.e., 20 micrometers in the filament brush and 25 micrometers in the flap brush. Wet polishing conditions were used for both brushes. The substrate surface polished with the filament brush had a gloss of 570, while the substrate surface polished with the flap brush had a gloss of only 151, or three and half times worse. These results were consistent with the results of the experiment described above. It was observed that polishing with a filament brush leads to a fewer divots on the polished surface and substantially higher gloss.

In yet another experiment, different sizes of silicon carbide particles were tested. All tests were performed using filament brushes and wet polishing conditions. A surface polished with a brush with 78 micrometer particles had a gloss of 135, 36 micrometer particles—a gloss of 395, and 20 micrometer particles—a gloss of 570. Up to a point, finer particles left smaller scratches on the surface resulting in higher gloss values. However, it was also determined that smaller particles, e.g., particles less than 1 micrometer in size, may not provide adequate polishing for certain substrates, such as rolled stainless steel foil. While a web feeding speed can be reduced for finer grit brushes, this will negatively impact process throughput.

### CONCLUSION

Although the foregoing invention has been described in some detail for purposes of clarity of understanding, it will be apparent that certain changes and modifications may be practiced within the scope of the appended claims. It should be noted that there are many alternative ways of implementing the processes, systems and apparatus of the present invention. Accordingly, the present embodiments are to be considered as illustrative and not restrictive, and the invention is not to be limited to the details given herein.

What is claimed is:

1. A method for processing a photovoltaic cell metallic substrate to remove surface defects from a substrate surface, the method comprising:
feeding a continuous web of the photovoltaic cell metallic substrate towards a first fixed-abrasive filament roller brush comprising a first plurality of filaments containing first fixed abrasive particles having an average size of between about 5 micrometers and 20 micrometers; and
contacting the substrate surface with the first brush while rotating the first brush such that at least some defects are removed from the substrate surface by the first brush to form a polished substrate surface.

2. The method of claim 1, wherein the first fixed abrasive particles comprise silicon carbide.

3. The method of claim 1, wherein the substrate comprises stainless steel.

4. The method of claim 1, where the continuous web is fed at between about 1 foot per minute and 20 feet per minute.

5. The method of claim 4, wherein the first brush rotates at between about 700 RPM and 1400 RPM.

6. The method of claim 1, wherein an average length of the first plurality of filaments is larger than a gap between a brush core of the first brush and the substrate surface by between about 0.1 inches and 0.5 inches.

7. The method of claim 5, wherein a diameter of the first brush is at least about 10 inches.

8. The method of claim 1, wherein the first brush is a close-wound coil type.

9. The method of claim 1, wherein a loading of the first fixed abrasive particles in the first plurality of filaments is between about 20% and 35%.

10. The method of claim 1, wherein a diameter of filaments in the first plurality of filaments is between about 0.005 inches and 0.030 inches.

11. The method of claim 1, wherein the web is at least partially supported in an area of contacting with the first brush.

12. The method of claim 11, wherein the web is supported by a stainless steel support roller.

13. The method of claim 1, further comprising delivering cooling liquid into a pinch area between the first brush and the web.

14. The method of claim 13, wherein during the contacting operation an average temperature of the cooling liquid stays under a temperature limit set to prevent substantial separation of the first fixed abrasive particles from the first plurality of filaments.

15. The method of claim 14, wherein the first plurality of filaments comprises nylon supporting the first fixed abrasive particles, and wherein the temperature limit is about 50° C.

16. The method of claim 1, wherein a gloss of the substrate surface measured at a 20° angle is at least doubled during the contacting operation.

17. The method of claim 1, wherein the metallic substrate has a thickness of between about 0.5 mils and 15 mils and a width of between about 0.3 meters and 3 meters.

18. The method of claim 1, wherein the rotational axis of the first brush is substantially parallel to the substrate surface.

19. The method of claim 18, wherein the first brush rotates in a direction counter to the feeding direction of the substrate.

20. The method of claim 1, further comprising contacting the substrate surface with a second fixed-abrasive filament roller brush while rotating the second brush such that additional surface defects are removed from the polished substrate surface by the second brush.

21. The method of claim 20, wherein the second brush rotates in an opposite direction relative to the first brush with reference to the substrate surface.

22. The method of claim 20, wherein the rotational axes of the first brush and the second brush are substantially parallel to the substrate surface, and wherein the first brush rotates in a direction counter to the feeding direction of the substrate, and the second brush rotates in the same direction as the feeding direction of the substrate.

23. The method of claim 20, wherein the second brush comprises second fixed abrasive particles that are smaller on average than the first fixed abrasive particles.

24. The method of claim 1, further comprising cleaning the web after the contacting operation by passing the web through one or more cleaning stations selected from the group consisting of a high pressure water jet, a drying air knife, a rinsing jet, and a rotating non-abrasive cleaning brush.

25. The method of claim 24, wherein the one or more cleaning stations comprise a set of two roller brushes configured to clean both sides of the substrate with a surfactant containing water solution.

26. The method of claim 1, further comprising depositing a photovoltaic absorber layer on the polished substrate surface.

27. The method of claim 26, wherein the photovoltaic absorber layer comprises a semiconductor material selected from the group consisting of copper indium gallium diselenide (CIGS), cadmium telluride (CdTe) and amorphous silicon (a-Si).

28. An apparatus for processing a photovoltaic cell metallic substrate to remove surface defects from a substrate surface, the apparatus comprising:
an unwind spool configured to feed a continuous web of the photovoltaic cell metallic substrate metallic substrate;
a first fixed-abrasive filament roller brush comprising a first plurality of filaments containing first fixed abrasive particles having an average size of between about 5 micrometers and 20 micrometers; and
a rewind spool configured to take up the web with a polished substrate surface.
